(19) United States
(12) Patent Application Publication
(10) Pub. No.: US 2016/0124545 A1
(43) Pub. Date: May 5, 2016

(54) TOUCH SUBSTRATE AND MANUFACTURING METHOD THEREOF, AND TOUCH DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Hefei City (CN)

(72) Inventors: Xiaodong XIE, Beijing (CN); Ming HU, Beijing (CN); Qingpu WANG, Beijing (CN); Kefeng LI, Beijing (CN)

(21) Appl. No.: 14/751,552

(22) Filed: Jun. 26, 2015

(30) Foreign Application Priority Data
Oct. 30, 2014 (CN) 201410605041.3

(51) Int. Cl. G06F 3/044; H05K 3/46; H05K 1/02; H05K 1/03

(52) U.S. Cl. CPC G06F 3/044; H05K 1/03; H05K 3/4644; H05K 1/0298; G06F 2203/04111; G06F 2203/04103; H05K 2201/0329

(57) ABSTRACT

A touch substrate and manufacturing method thereof, and a touch display device are provided. The touch substrate includes: a substrate; a plurality of first electrodes alternatively arranged in a first direction of the substrate, a plurality of second electrodes alternatively arranged in a second direction of the substrate, and adjacent first electrodes are electrically interconnected in the adjacent areas; an isolating layer provided on the adjacent areas, and the isolating layer covering a portion of an area that is adjacent to the second electrode; and a bridge provided on the isolating layer. The bridge connects adjacent second electrodes; and the bridge includes an organic polymer conducting material. The performance of the touch substrate is improved effectively.

### TECHNICAL FIELD

Embodiments of the present invention relate to a touch substrate and its manufacturing method, a touch display panel and a touch display device.

### BACKGROUND

Currently, signal emitting (driving) or receiving (inducing) in direction x and direction y in a single layer are achieved by a bridge structure. As shown in FIGS. 1 and 2, a pattern process is usually adopted to form an electrode 1 in the direction x and the direction y in a same layer of a substrate 5, wherein electrodes 12 in the direction x or the direction y are interconnected directly, and then an isolating layer is made in the adjacent area 4, a bridge 3 is made on the isolating layer 2, and the bridge 3 connects the non-connected electrodes 11 in the direction x or the direction y through a via hole. Typically, the bridge 3 has a pattern in a rectangular shape and connected with the electrode 12 at two ends.

### SUMMARY

Embodiments of the present invention provide a touch substrate, including: a substrate; a plurality of first electrodes alternatively arranged in a first direction of the substrate, a plurality of second electrodes alternatively arranged in a second direction of the substrate, and adjacent first electrodes being electrically interconnected in the adjacent areas; an isolating layer provided on the adjacent areas, and the isolating layer covers a portion of an area that is adjacent to the second electrode; and a bridge provided on the isolating layer, wherein the bridge connects adjacent second electrodes, and the bridge includes an organic polymer conducting material.

Another embodiment of the present invention provides a method of manufacturing the touch substrate, including: forming a plurality of first electrodes alternatively arranged in a first direction of the substrate and forming a plurality of second electrodes alternatively arranged in the second direction of the substrate through a pattern process, wherein adjacent first electrodes are electrically interconnected in adjacent areas; forming an isolating layer on the substrate through a pattern process, and the isolation layer covering a portion of an area that is adjacent to the second electrode; and forming a bridge on the isolation layer by an organic polymer conducting material on the substrate through a pattern process, wherein the bridge electrically interconnects adjacent second electrodes.

Another embodiment of the present invention further provides a touch display panel, and the touch display panel includes the touch substrate.

Another embodiment of the present invention further provides a touch display device, including the touch display panel.

### BRIEF DESCRIPTION OF THE DRAWINGS

FIG. 1 is a partial top view of a touch substrate;

FIG. 2 is a partial cross-sectional view of the touch substrate;

FIG. 3 is a partial cross-sectional view of the touch substrate according to embodiment 1 of the present invention;

FIG. 4 is a formula of 3,4-ethylenedioxythiophene polymer according to embodiment 1 of the present invention;

FIG. 5 is a formula of poly(3,4-ethylenedioxythiophene)-poly(styrenesulfonic acid) according to embodiment 1 of the present invention;

FIG. 6 is a top view of the bridge of the touch substrate which expansion portion is in an arc shape according to embodiment 1 of the present invention; and

FIG. 7 is a top view of the bridge of the touch substrate which expansion portion is in a trapezium form according to embodiment 1 of the present invention.

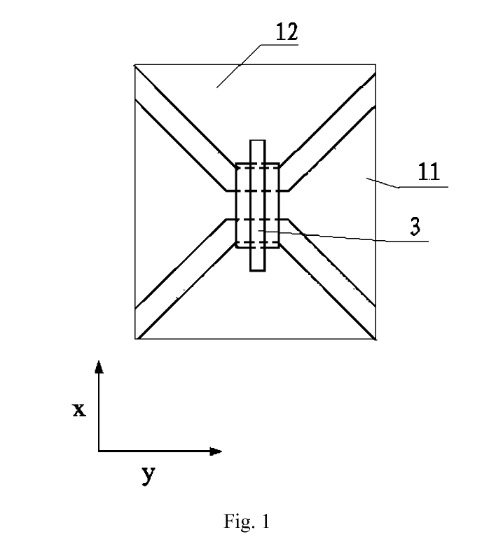

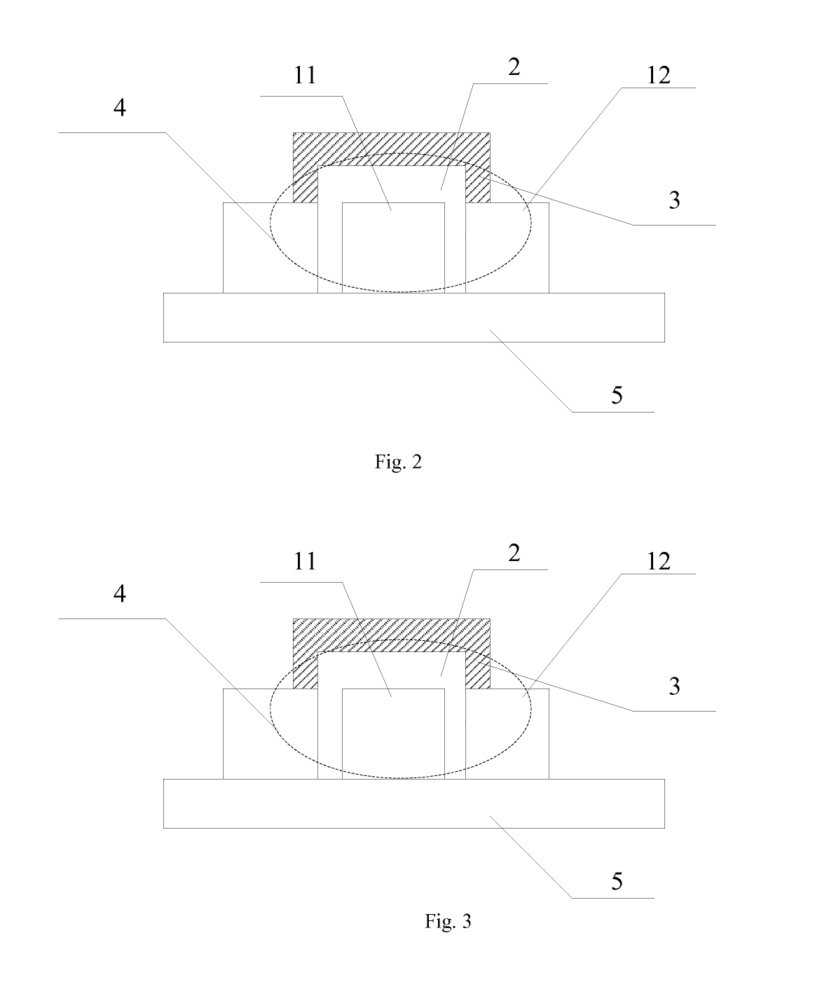

### DETAILED DESCRIPTION

The technical solutions of the embodiments of the present disclosure will be described in a clearly and fully understandable way in connection with the drawings related to embodiments of the disclosure. Apparently, the described embodiments are just a part but not all of the embodiments of the disclosure. Based on the described embodiments herein, those skilled in the art can obtain other embodiment(s), without any inventive work, which shall fall within the protection scope of the present disclosure.

Unless otherwise defined, all the technical and scientific terms used herein have the same meanings as commonly understood by one of ordinary skill in the art to which the present disclosure belongs. The terms, such as “first,” “second,” or the like, which are used in the description and the claims of the present application, are not intended to indicate any sequence, amount or importance, but for distinguishing various components. Also, the terms, such as “a/an,” “one,” or the like, are not intended to limit the amount, but for indicating the existence of at lease one. The terms, such as “comprise/comprising,” “include/including,” or the like are intended to specify that the elements or the objects stated before these terms encompass the elements or the objects and equivalents thereof listed after these terms, but not preclude other elements or objects. The terms, “on,” “under,” or the like are only used to indicate relative position relationship, and when the position of the object which is described is changed, the relative position relationship may be changed accordingly.

The inventors notice that a bridge is typically made by a transparent metal or a metal oxide, for example, indium tin oxide (ITO) is typically used. Typically, the bridge material must satisfy certain electrical performance, for example, the sheet resistance should be below 50 Ωsq⁻¹, so that the thickness of the ITO must be increased if the ITO is adopted as the bridge material. However, a too thick bridge material will render a bridge point easily appearing, and meanwhile, then a decreased transmittance will affect touch display effect. If a metal is used as the bridge material, the light reflection of the metal is relative large, and the reflection of the bridge point is significant and cause easy appearance of the bridge. The bridge is typically designed in a rectangular shape, but such a design easily renders deformation in the manufacturing process, and the two ends of the bridge become tips so that the ability for antistatic of a touch unit is compromised.

Embodiments of the present invention provide a touch substrate and its manufacturing method, a touch display panel and a touch display device, and as the bridge of the embodiments is made of an organic polymer conducting material, the performance of the touch substrate is improved effectively. For example, the sheet resistance of the organic polymer conducting material can be reduced to 46.1 Ωsq⁻¹, and the transmittance can be above 90%, thus, the speed of signal transmission is enhanced while fine passing rate is achieved.

### Embodiment 1

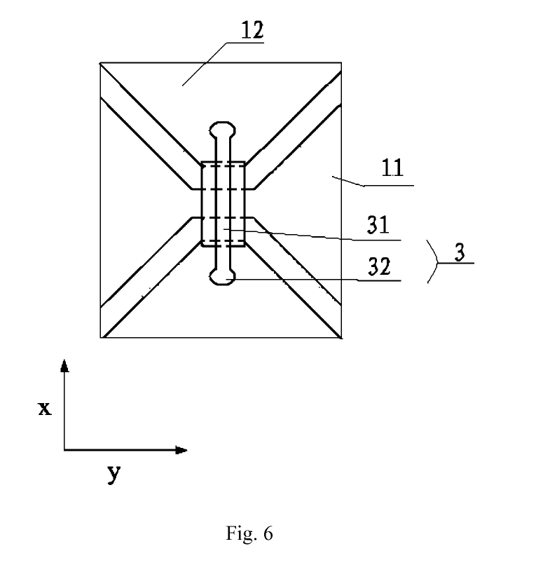

As shown in FIGS. 3, and 6-7, the present embodiment provides a touch substrate, including: a substrate 5; a plurality of first electrodes 11 alternatively arranged in a first direction (direction y in FIG. 6) of the substrate 5, a plurality of second electrodes 12 alternatively arranged in a second direction (direction x in FIG. 6) of the substrate 5. For example, the substrate may be made of glass, plastic, or quartz.

The adjacent first electrodes 11 are electrically interconnected in adjacent areas 4.

An isolating layer 2 is provided in the adjacent areas 4. The isolating layer 2 covers a portion of an area that is adjacent to the second electrode 12.

A bridge 3 is provided on the isolating layer 2. The bridge 3 electrically connects adjacent second electrodes 12. The bridge 3 is made of an organic polymer conducting material.

In the present embodiment, the bridge 3 is made of an organic polymer conducting material, such that the performance of the touch substrate is improved effectively. For example, the sheet resistance of the organic polymer conducting material can be reduced to 46.1 Ωsq⁻¹, and the transmittance can be above 90%. Therefore, the speed of signal transmission is enhanced while fine passing rate is achieved.

For example, the organic polymer conducting material includes 3,4-ethylenedioxythiophene polymer and derivatives thereof. The structural formula of the 3,4-ethylenedioxythiophene polymer is as shown in FIG. 4. In addition, the derivatives can be formed by reaction of the 3,4-ethylenedioxythiophene polymer with other materials.

As the 3,4-ethylenedioxythiophene polymer and derivatives thereof have advantages of low energy gap, low electrochemical doping potential, short response time, high color change contrast, good stability and etc., and are adapted to manufacture the bridge 3 with high transmittance and low sheet resistance.

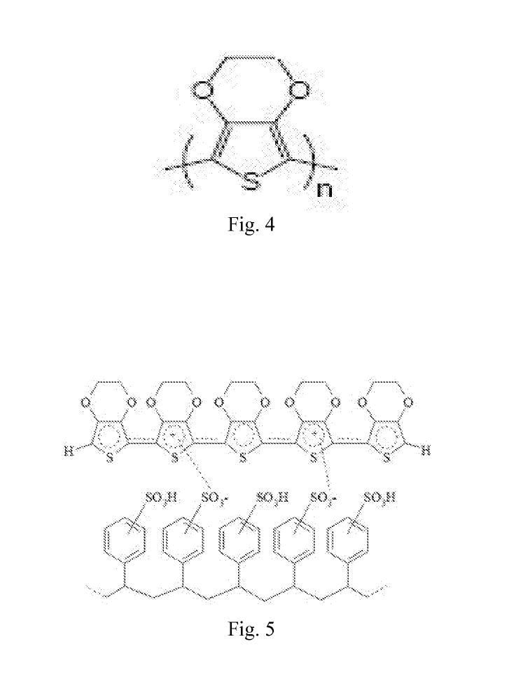

For example, the 3,4-ethylenedioxythiophene polymer and derivatives thereof include poly(3,4-ethylenedioxythiophene)-poly(styrenesulfonic acid), and the structural formula is as shown in FIG. 5. For example, the polymer can be EL-P4010, EL-P4020, EL-P3040, P-3042, EL-P3145, EL-P6010 or the like manufactured by Belgium Agfa material company.

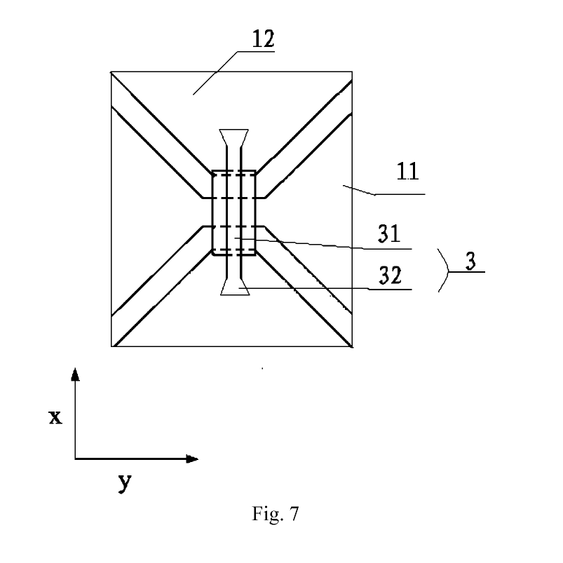

As shown in FIGS. 6 and 7, the bridge 3 includes an expansion portion 32 at the two ends and a main body portion 31 that connects the expansion portions 32, and the expansion portions 32 have a width greater than that of the main body portion 31.

In the present embodiment, the bridge 3 has a figure designed in such a way that the width of the expansion portion 32 is greater than that of the main body portion 31, so that it can effectively tackle the problem that the antistatic ability of the touch substrate is reduced due to the etching accuracy in the manufacturing process which renders sharp tips at two ends of the main body of the bridge.

As shown in FIG. 6, the expansion portion 32 is in an arc shape, and the connecting line of the two end points of the arc shape substantially coincides with the center line of the main body portion 31.

As shown in FIG. 7, the expansion portion 32 is in a trapezium shape, and the short bottom of the trapezium is substantially equal to the width of the main body portion 31.

It should be understood that the above expansion portion 32 can also be in other shapes, and its width is greater than that of the main body portion 31. For example, the expansion portion 32 can be in an elliptical shape or other shape or profile.

### Embodiment 2

The present embodiment provides a method of manufacturing the touch display panel, including following steps.

S1, forming a plurality of first electrodes alternatively arranged in a first direction of a substrate 5 and forming a plurality of second electrodes 12 alternatively arranged in a second direction of the substrate 5 through a pattern process, wherein adjacent first electrodes are electrically connected in adjacent areas 4.

For example, as shown in FIG. 6, a plurality of first electrodes 11 are alternatively arranged in a first direction (direction y in FIG. 6) of a substrate and a plurality of second electrodes 12 are alternatively arranged in a second direction (direction x in FIG. 6) of the substrate 5, and the adjacent first electrodes are electrically interconnected in the adjacent areas 4. For example, the substrate may be made of glass, plastic, or quartz.

S2, as shown in FIG. 3, forming an isolation layer 2 on the substrate 5 through a pattern process, and the isolation layer 2 covering a portion of areas that is adjacent to the second electrode 12.

S3, as shown in FIG. 3, forming a bridge 3 on the isolation layer 2 by adopting the organic polymer conducting material on the substrate 5 through a pattern process, and the bridge 3 electrically connects adjacent second electrodes 12.

For example, the poly(3,4-ethylenedioxythiophene)-poly(styrenesulfonic acid) can be subjected to sulfuric acid treatment after film forming e.g., it is immersed into the sulfuric acid after being coated, so that the polymer changes from amorphous material into crystalline material, and the crystal form can be arranged orderly, and the sheet resistance is further reduced and the light transmittance is further improved.

In such a way, it can allow the first electrodes 11 and the second electrodes 12 to be disposed in a same layer and do not affect each other. As the organic polymer conducting material is adopted to manufacture the bridge, the performance of the touch substrate is improved effectively. For example, the sheet resistance of the organic polymer conducting material can be reduced to 46.1 Ωsq⁻¹, and the transmittance can be above 90%. Therefore, the speed of signal transmission is enhanced while fine passing rate is achieved.

Optionally, other necessary functional layers can also be made on the substrate, and the other functional layers can be made with conventional manufacturing ways which will not described in detail herein.

### Embodiment 3

The present embodiment provides a touch display panel, and the touch display panel includes the touch substrate.

### Embodiment 4

The present embodiment provides a touch display device, and the touch display device includes the touch display panel.

It is understood that the described above are only illustrative implementation or embodiments for explaining the principle of the present invention, but the present invention is not limited thereto. A person of ordinary skill in the art can make various modifications and improvements without departing from the spirit and nature of the present invention which shall fall within the scope of the present invention.

The present application claims the priority of the Chinese patent application No. 201410605041.3, entitled “A touch substrate and a method of manufacturing the same, a touch display panel, a touch display device” and filed on Oct. 30, 2014, which is entirely incorporated herein by reference.

What is claimed is:

1. A touch substrate, comprising:
a substrate;
a plurality of first electrodes alternatively arranged in a first direction of the substrate, and a plurality of second electrodes alternatively arranged in a second direction of the substrate, wherein adjacent first electrodes being electrically interconnected in adjacent areas;
an isolating layer provided in the adjacent areas, which covers a portion of an area that is adjacent to the second electrode; and
a bridge provided on the isolating layer, wherein the bridge connects adjacent second electrodes; and
wherein the bridge comprises an organic polymer conducting material.

2. The touch substrate according to claim 1, wherein the organic polymer conducting material comprises 3,4-ethylenedioxythiophene polymer and derivatives thereof.

3. The touch substrate according to claim 2, the 3,4-ethylenedioxythiophene polymer and derivatives thereof comprise poly(3,4-ethylenedioxythiophene)-poly(styrenesulfonic acid).

4. The touch substrate according to claim 2, wherein the bridge comprises an expansion portion at two ends and a main body portion that connects the expansion portions, and the expansion portions have a width greater than that of the main body portion.

5. The touch substrate according to claim 4, wherein the expansion portions are in a trapezium shape, and the short bottoms of the trapeziums have a width substantially equal to that of the main body portion.

6. The touch substrate according to claim 4, wherein the expansion portions are in an arc shape, and the connecting line of the two end points of the arc shape coincides with the center line of the main body portion.

7. The touch substrate according to claim 4, wherein the expansion portions are in an elliptical shape, and the connecting line of the two end points of the elliptical shape coincides with the center line of the main body portion.

8. A method of manufacturing a touch substrate, comprising:
forming a plurality of first electrodes alternatively arranged in a first direction of a substrate and forming a plurality of second electrodes alternatively arranged in a second direction of the substrate through a pattern process, wherein adjacent first electrodes are electrically connected in adjacent areas;
forming an isolating layer on the substrate through a pattern process, and the isolation layer covering a portion of an area that is adjacent to the second electrodes; and
forming a bridge on the isolation layer by an organic polymer conducting material on the substrate through a pattern process, wherein the bridge electrically interconnects adjacent second electrodes.

9. The method according to claim 8, wherein the organic polymer conducting material comprises 3,4-ethylenedioxythiophene polymer and derivatives thereof.

10. The touch substrate according to claim 9, the 3,4-ethylenedioxythiophene polymer and derivatives thereof comprise poly(3,4-ethylenedioxythiophene)-poly(styrenesulfonic acid).

11. A touch display device, comprising the touch substrate of claim 1.

12. The touch substrate according to claim 1, wherein the bridge comprises expansion portions at two ends and a main body portion that connect the expansion portions, and the expansion portions have a width greater than that of the main body portion.

13. The touch substrate according to claim 3, wherein the bridge comprises expansion portions at the two ends and a main body portion that connect the expansion portions, and the expansion portions have a width greater than that of the main body portion.
